(19) United States
(12) Patent Application Publication
(10) Pub. No.: US 2013/0277839 A1
(43) Pub. Date: Oct. 24, 2013

(54) CHIP PACKAGE AND METHOD FOR ASSEMBLING SAME

(71) Applicant: KAI-WEN WU, Tu-Cheng (TW)

(72) Inventor: KAI-WEN WU, Tu-Cheng (TW)

(73) Assignee: HON HAI PRECISION INDUSTRY CO., LTD., Tu-Cheng (TW)

(21) Appl. No.: 13/533,024

(22) Filed: Jun. 26, 2012

(30) Foreign Application Priority Data
Apr. 20, 2012 (TW) 101114040

(51) Int. Cl. H01L 23/498; H01L 21/50

(52) U.S. Cl. 257/738; 438/125; 257/E23.069; 257/E21.499

(57) ABSTRACT

A chip package includes a PCB, a chip positioned on the PCB and bonding wires electrically connecting the chip to the PCB. The PCB includes a number of first bonding pads formed thereon. Each first bonding pad includes a first soldering ball. The chip includes a number of second bonding pads. Each second bonding pad includes a second bonding ball. Each bonding wire electrically connects a first bonding pad to a corresponding second bonding ball. Each bonding wire forms a vaulted portion upon the first bonding ball.

### BACKGROUND

1. Technical Field

The present disclosure relates to a chip package and a method for assembling the chip package.

2. Description of Related Art

To achieve predetermined functions, an electronic device typically includes a printed circuit board (PCB) and a number of chips packaged on the PCB. The chips and the PCB may have different heights. The chips are connected to each other or the PCB via bonding wires. The bonding wires are connected to the chips and/or the PCB by a pressure welding manner. However, when connecting the bonding wire to the chips by the pressure welding manner, the chips may be damaged by a welding pressure.

What is needed therefore is a chip package and a method for assembling the chip package addressing the limitations described.

### BRIEF DESCRIPTION OF THE DRAWINGS

The components of the drawings are not necessarily drawn to scale, the emphasis instead being placed upon clearly illustrating the principles of the embodiments of the present disclosure. Moreover, in the drawings, like reference numerals designate corresponding parts throughout several views.

FIG. 1 is a schematic view of a chip package, according to an exemplary embodiment of the present disclosure.

FIG. 3 a flowchart of a method for assembling a chip package, according to an exemplary embodiment of the present disclosure.

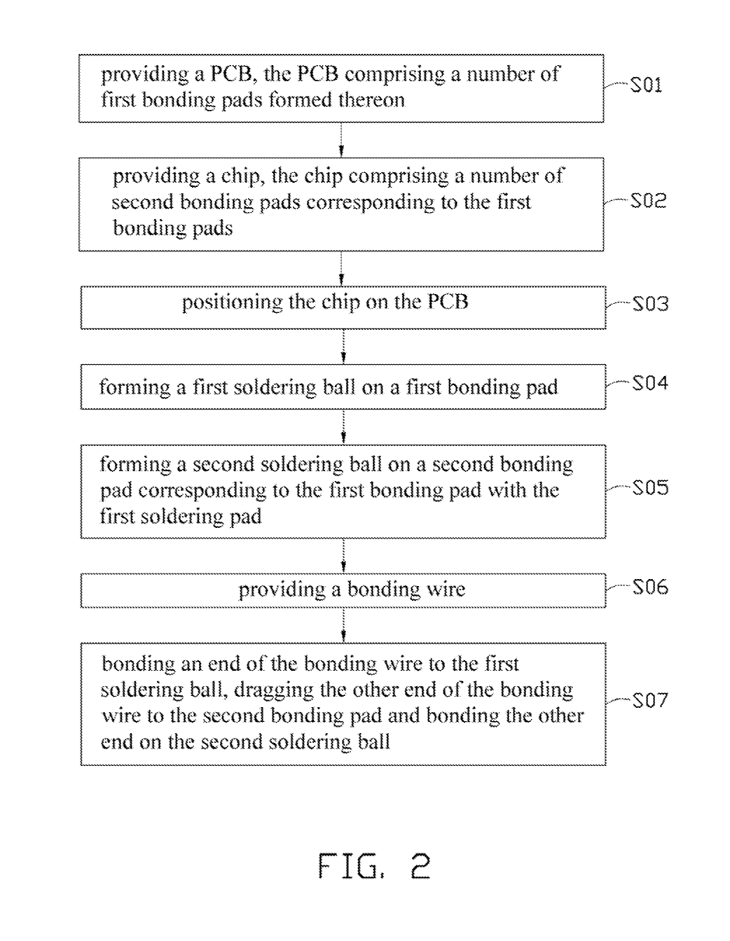

### DETAILED DESCRIPTION

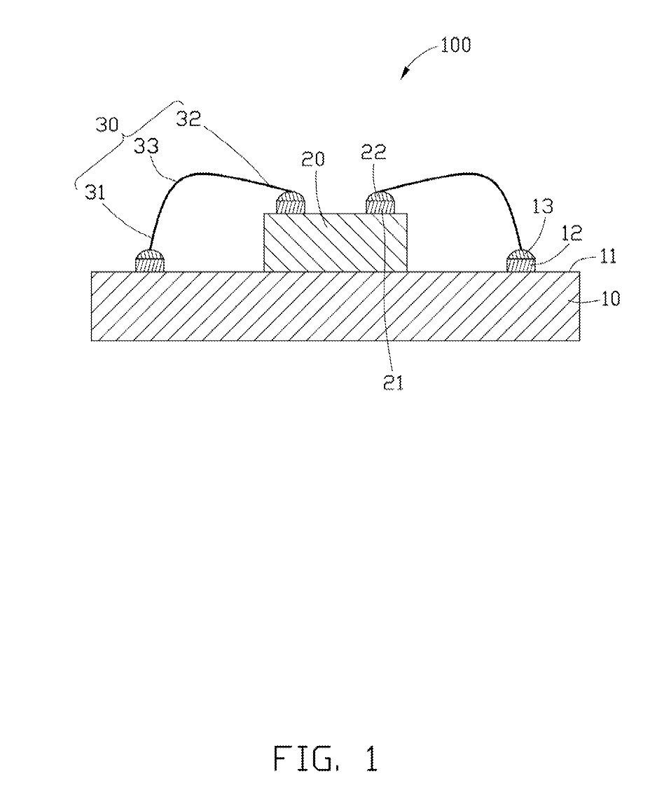

Referring to FIG. 1, a chip package 100, according to an exemplary embodiment, is shown. The chip package 100 includes a PCB 10, a chip 20 positioned on the PCB 10, and a number of bonding wires 30 electrically connecting the chip 20 to the PCB 10.

The PCB 10 includes a mounting surface 11 and a number of first bonding pads 12 formed on the mounting surface 11. Each bonding pad 12 includes a soldering ball 13 formed thereon.

The chip 20 includes a number of second bonding pads 21 formed on a surface facing away from the PCB 10. The second bonding pads 21 correspond to the first bonding pads 12. Each second bonding pad 21 includes a second soldering pad 22 formed thereon.

The bonding wires 30 each electrically connect a first bonding pad 12 to a corresponding second bonding pad 21. Each bonding wire 30 includes a beginning end 31 and an opposite ending end 32 and a vaulted portion 33 between the beginning end 31 and the ending end 32. The beginning end 31 is an end of the bonding wire 30 which is firstly bonded, and the ending end 31 is an end of the bonding wired 30 which is lastly bonded. The vaulted portion 33 is a portion which is formed by dragging the bonding wire 30 from the first soldering pad 12 to the second soldering pad 21. The vaulted portion 33 is adjacent to a top of the first soldering ball 13 and a height of the vaulted portion 33 is substantially equal to a height of the second soldering ball 22.

The first soldering pads 13, the second soldering pads 22 and the bonding wires 30 are made from a material(s) with high conductivity. In the embodiment, the first soldering balls 13, the second soldering balls 22 and the bonding wires 30 are made from gold.

FIG. 1 only shows a chip 20 positioned on the PCB 10. However, the number of the chip on the PCB can be more than one, and the chips may have different heights. The chips also can be connected to each other by bonding wires similar as the bonding wires 30. The beginning end of each bonding wire is bonded to a lower chip and the ending end is bonded to a higher chip. The vaulted portion is adjacent to a top of the beginning end.

Referring to FIG. 2, a flowchart of a chip assembling method of the present disclosure is show. The chip assembling method includes the following steps.

In step S01, a PCB is provided. The PCB includes a number of first bonding pads formed thereon.

In step S02, a chip is provided. The chip includes a number of second bonding pads corresponding to the first bonding pads.

In step S03, the chip is positioned on the PCB, a surface of chip with the second bonding pads is away from the PCB.

In step S04, a first soldering ball is formed on a first bonding pad.

In step S05, a second soldering ball is formed on a second bonding pad.

In step S06, a bonding wire is provided.

In step S07, an end of the bonding wire is bonded to the first soldering ball, and the other end of the bonding wire is dragged to the second bonding pad and is bonded on the second soldering ball. A vaulted portion of the bonding wire is formed upon the first bonding ball. The vaulted portion is adjacent to a top of the first soldering ball and a height of the vaulted portion is substantially equal to a height of the second soldering ball.

It should be noted that the above chip assembling method just described how to electrically a first bonding pad to a corresponding second bonding pad. The other first bonding pads can be electrically connected to the corresponding second bonding pad by a similar method.

The chip package and the method for assembling the chip package forms soldering balls both on the first bonding pads and the second bonding pads, thus a welding pressure to bond the bonding wires to the second soldering ball is decreased, accordingly, the quality of the chip is ensured. In addition, each bonding wire is dragged from a first bonding pad to a corresponding second bonding pad, thus the vaulted portion are formed upon the first soldering ball, as such, a height of the bonding wire can be controlled substantially equal to that of the second soldering ball, therefore, a height of the chip package is reduced.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A chip package comprising:
a PCB comprising a plurality of first bonding pads formed thereon, each first bonding pad comprising a first soldering ball;
a chip positioned on the PCB, the chip comprising a plurality of second bonding pads, each second bonding pad comprising a second bonding ball; and
a plurality of bonding wires, each of the bonding wires electrically connecting a respective first bonding pad to a respective second bonding ball, each bonding wire comprising a vaulted portion upon the respective first bonding ball.

2. The chip package of claim 1, wherein each bonding wire comprises a beginning end and an opposite ending end, the beginning end is firstly bonded to the respective first soldering ball, the ending end is finally bonded to the respective second soldering ball, and the vaulted portion is connected between the beginning end and the ending end.

3. The chip package of claim 1, wherein a height of the vaulted portion is substantially equal to a height of the respective second soldering ball.

4. The chip package of claim 1, wherein the first soldering pads, the second soldering pads and the bonding wires are made from gold.

5. A chip assembling method, comprising:
providing a PCB, the PCB comprising a plurality of first bonding pads formed thereon;
providing a chip, the chip comprising a plurality of second bonding pads;
positioning the chip on the PCB;
forming a first soldering ball on each of the first bonding pads;
forming a second soldering ball on each of the second bonding pads;
providing a plurality of bonding wires; and
bonding an end of each of the bonding wires to a respective first soldering ball, dragging the other end of each of the bonding wires to a respective second bonding pad and bonding the other end on the respective second soldering ball, and forming a vaulted portion of each bonding wire upon the respective first bonding ball during dragging each bonding wire.

6. The chip assembling method of claim 5, wherein a height of the vaulted portion is substantially equal to a height of the respective second soldering ball.

7. The chip assembling method of claim 5, wherein the first soldering pads, the second soldering pads and the bonding wires are made from gold.
